(19) United States
(12) Patent Application Publication
(10) Pub. No.: US 2013/0176062 A1
(43) Pub. Date: Jul. 11, 2013

(54) TIME DELAY CIRCUIT AND METHOD OF GENERATING TIME DELAYED SIGNAL

(71) Applicants: Li-Wen WANG, Taichung City (TW); Yen-Huei CHEN, Jhudong Township (TW)

(72) Inventors: Li-Wen WANG, Taichung City (TW); Yen-Huei CHEN, Jhudong Township (TW)

(73) Assignee: TAIWAN SEMICONDUCTOR MANUFACTURING COMPANY, LTD., Hsinchu (TW)

(21) Appl. No.: 13/345,101

(22) Filed: Jan. 6, 2012

(51) Int. Cl. H03L 7/00

(52) U.S. Cl. 327/161

(57) ABSTRACT

A delay circuit includes an input port, an output port, a first delay circuit block, a second delay circuit block, and an inverter module. The first delay circuit block is coupled to the input port and configured to generate an intermediate signal by applying a first delay to an input signal. The inverter module has an input terminal and an output terminal. The input terminal of the inverter module is coupled to the first delay circuit block, and the inverter module is configured to generate an inverted intermediate signal at the output terminal. The second delay circuit block is coupled to the output terminal of the inverter module and configured to generate a delayed signal by applying a second delay to the inverted intermediate signal.

### BACKGROUND

In an integrated circuit (IC), digital signals are processed by stages of digital circuit blocks. During the signal processing, signals pass through different numbers of gates, and the timing of some signals may need to be delayed in order to synchronize the signals before moving forward to the digital circuit block of the next stage. As operational frequencies of integrated circuits increase, the complexity of controlling time delays among digital circuit blocks increases. Further, the delayed signals become more vulnerable to distortions caused by the digital circuit devices used in a delay circuit such as metal-oxide semiconductor field effect transistors (MOSFETs).

### BRIEF DESCRIPTION OF DRAWINGS

One or more embodiments are illustrated by way of example, and not by limitation, in the FIGs. of the accompanying drawings. It is emphasized that in accordance with the standard practice in the industry various features may not be drawn to scale and are used for illustration purposes only. In fact, the dimensions of the various features in the drawings may be arbitrarily increased or reduced for clarity of discussion.

FIG. 1 is a schematic diagram of a delay circuit in accordance with one or more embodiments.

FIG. 2 is a schematic diagram of another delay circuit in accordance with one or more embodiments.

FIG. 3 is a block diagram of a delay circuit in accordance with one or more embodiments.

FIG. 4 is a block diagram of a delay circuit block usable as the delay circuit block depicted in FIG. 3 in accordance with one or more embodiments.

FIG. 5 is a table of simulation results of a delay circuit based on an embodiment depicted in FIG. 3.

FIG. 6 is a flow chart of a method of generating a delayed signal in accordance with one or more embodiments.

### DETAILED DESCRIPTION

The following disclosure provides many different embodiments, or examples, for implementing different features of the invention. Specific examples of components and arrangements are described below to simplify the present disclosure. These are, of course, examples and are not intended to be limiting.

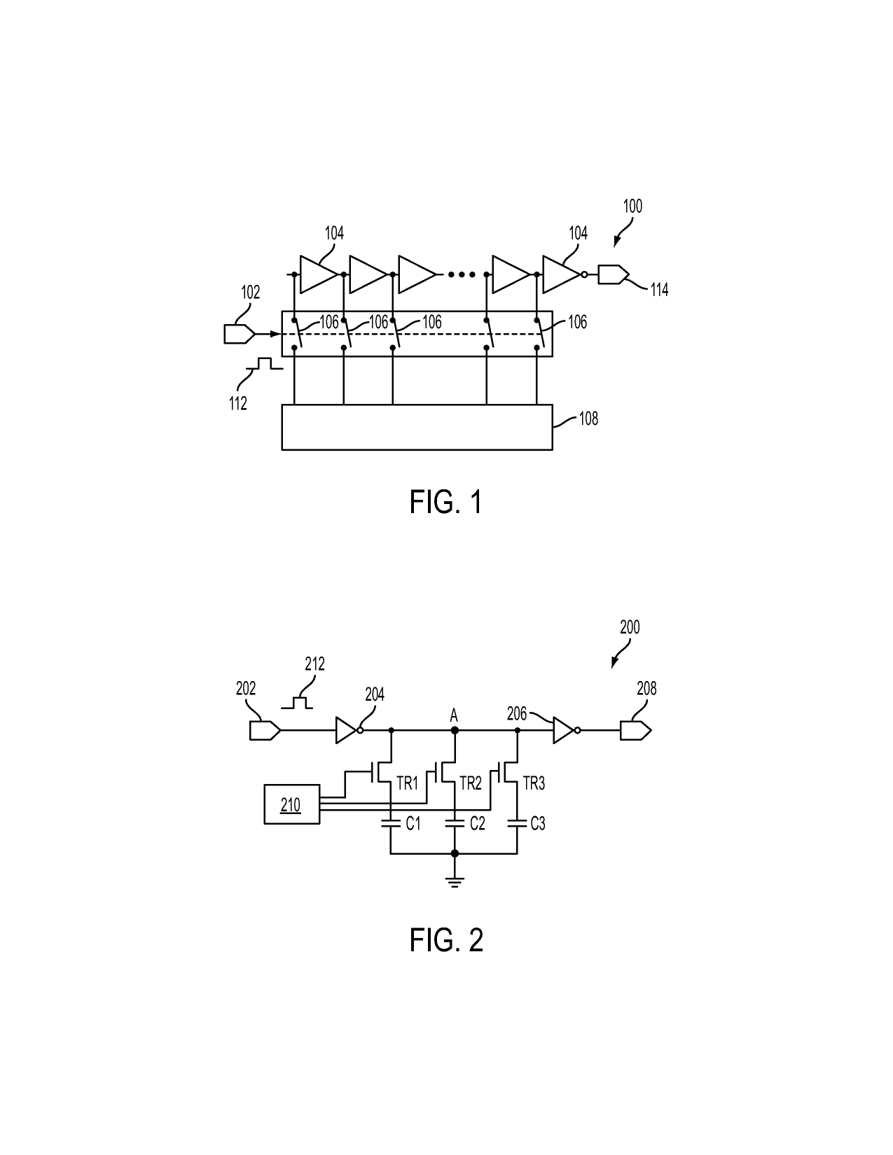

FIG. 1 is a schematic diagram of a delay circuit 100 in accordance with an embodiment and comprising an input port 102, a plurality of delay elements 104, a plurality of switching elements 106, a controller 108, and a output port 114. In some embodiments, an input signal 112 input at the input port 102 is a clock signal, a reference timing signal, or a data signal read from a static random access memory (SRAM) or other data storage device, or another electrical device. Delay circuit 100 causes a time delay to be applied to the input signal 112. In some embodiments, delay elements 104 are selectively activated by switching elements 106 controlled by the controller 108. In at least one embodiment, delay elements 104 individually cause an approximately 20 picosecond (ps) time delay to a signal transiting the delay element 104. The total time delay applied to the signal 112 is determined by the number of activated delay elements 104. The delay circuit 100 is configurable by using the controller 108 such that the number of delay elements 104 is selected by closing switching elements 106 to provide a predetermined time delay. The delay circuit generates a delayed signal at the output port 114.

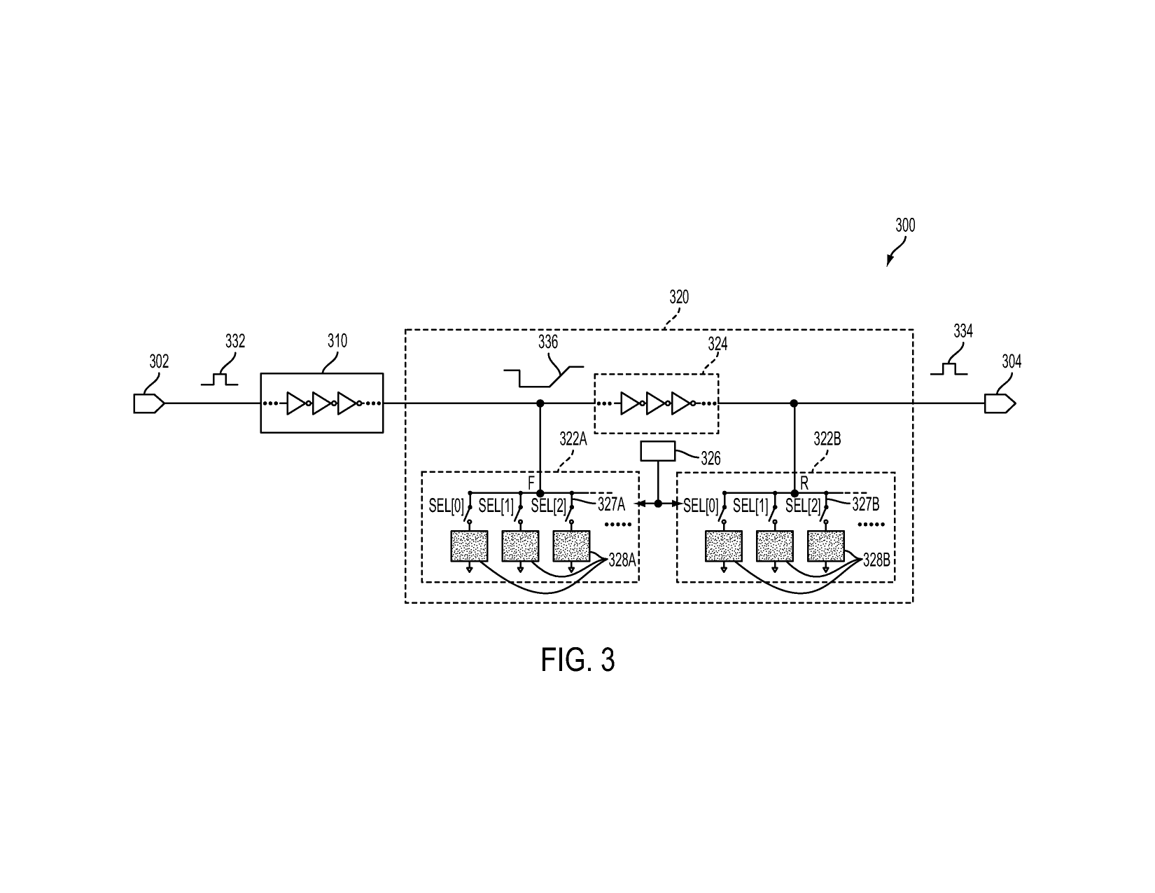

FIG. 2 is a schematic diagram of a delay circuit 200 in accordance with an embodiment and comprising an input port 202 that receives an input signal 212, a first inverter 204 coupled to the input port 202, a second inverter 206, an output port 208 coupled to the second inverter 206, a controller 210, and a number of transistors TR1, TR2, and TR3 and corresponding capacitors C1, C2, C3. The transistors TR1, TR2, and TR3 are coupled to and controlled by the controller 210. Capacitors C1, C2, and C3 are selectively coupled to node A between the first inverter 204 and the second inverter 206 by selectively turning on or off transistors TR1, TR2, and TR3. In some embodiments, the controller 210 individually controls the on or off state of the transistors TR1, TR2, and TR3. The inverter 204 thus charges or discharges the capacitors C1, C2, and C3 coupled at node A, which causes a delay of signal transmission between inverters 204 and 206. Therefore, the signal 212 transiting from the input port 202 to the output port 208 is delayed by a predetermined time delay. The magnitude of the time delay is dependent on the number and capacitance of capacitors C1, C2, and C3 coupled to node A. In some embodiments, the controller 310 in FIG. 3 is a logic circuit that translates an external delay command into the control signals to turn on or off the transistors TR1, TR2, and TR3. In at least one embodiment, the TR1, TR2, and TR3 are controlled by control signals transmitted from a logic circuit outside of the delay circuit 200, and the controller 310 is omitted.

As depicted in FIG. 2, the input signal 212 is received by the delay circuit 200 at input port 202 and inverted by first inverter 204. The first inverter 204 also works as a driver for charging or discharging the capacitor(s) coupled to node A. The controller 210 selectively turns on one or more of the transistors TR1, TR2, and/or TR3 in order to selectively couple corresponding capacitors C1, C2, or C3 to node A. The input signal 212 is time delayed due to the charging or discharging of the capacitor(s) coupled to node A by the inverter 204 in response to the input signal 212. As the capacitance driven by the inverter 204 increases by selectively coupling one or more capacitors C1, C2, or C3 to node A, the magnitude of the delay also increases. The time delay is a function of the time required to charge or discharge the capacitors C1, C2, and/or C3. Second inverter 206 inverts the previously inverted signal at node A and outputs the delayed signal at the output port 208. By adjusting the size and number of capacitors C1, C2, or C3, the delay circuit 200 is capable of applying a time delay to the input signal 212 at a finer resolution than that of the delay circuit 100. In some embodiments, each capacitor C1, C2, or C3 is capable of providing several picoseconds of time delay.

In some embodiments, the capacitors C1, C2, and C3 are made of semiconductor materials or are MOSFETs connected as capacitors. Therefore, the characteristics of the capacitors when forward biased differ from the characteristics of the capacitors when reversed biased. In some embodiments, the loading driven by the inverter 204 in the delay circuit 200 varies and causes different or mismatched distortions for charging or discharging the capacitors C1, C2, or C3 in response to the rising or falling edge of the input signal 212. As a result, in some embodiments, the pulse width and/or pulse shape of the signal at the output port 208 differs from that at the input port 202.

FIG. 3 is a block diagram of a delay circuit 300 in accordance with one or more embodiments and comprising an input port 302, a coarse tuning module 310 coupled to the input port, a fine tuning module 320 coupled to the coarse tuning module 310, and an output port coupled to the fine tuning module 320. In some embodiments, the coarse tuning module 310 includes one or more serially connected inverters. In some embodiments, the coarse tuning module 310 includes a chain of inverters controlled by a control circuit, such as the embodiment depicted in FIG. 1. In some embodiments, the coarse tuning module 310 is omitted, and the input port is directly coupled to the fine tuning module 320.

Fine tuning module 320 comprises a first delay circuit block 322A, an inverter module 324, a second delay circuit block 322B, and a controller 326 configured to control both the first delay circuit block 322A and the second delay circuit block 322B using control signals SEL[0:2]. The inverter module has an input terminal coupled to a node F and an output terminal coupled to a node R. The first delay circuit block 322A has a plurality of switches 327A controlled by the controller 326 in order to selectively couple one or more of fine delay unit 328A to the node F. The second delay circuit block 322B also has a plurality of switches 327B controlled by the controller 326 in order to selectively couple one or more of fine delay units 328B to the node R. In some embodiments, there are more or less than three sets of switches 327A and 327B and fine delay units 328A and 328B in each of the delay circuit block 322A and 322B. In at least one embodiment, the control signals SEL[0:2] are signals transmitted from a logic circuit outside of the delay circuit 300, and the controller 326 is omitted.

The first delay circuit block 322A and the second delay circuit block 322B have the same configuration. A switch of the set of switches 327A in the first delay circuit block 322A and a counterpart switch of the set of switches 327B in the second delay circuit block 322B are turned on or off in response to the same control signal, such as SEL[0], SEL[1], or SEL[2], from controller 326. The inverter module 324 translates a rising edge of a received signal into a falling edge, and vice versa, by inverting the signal. Therefore, the first delay circuit block 322A and the second delay circuit block 322B together are capable of causing a similar level or distortion change to both rising and falling edges of the signal transiting the fine tuning module 320. In some embodiments, the fine delay units 328A and 328B are capacitors, and the first delay circuit block 322A and the second delay circuit block 322B have the same configuration as depicted in FIG. 2. In some embodiments, the inverter module 324 has an odd number of serially connected inverters, such as one, three, or five inverters, etc.

For example, responsive to receipt of an input signal 332, delay circuit 300 generates a delayed signal 334 at the output port 304. First, the input signal 332 is received by the coarse tuning module 310 and generates an intermediate signal 336 at node F according to the number of buffers or inverters of the coarse tuning module 310. In at least some embodiments, the coarse tuning module 310 is a delay circuit such as delay circuit 100 of FIG. 1. The coarse tuning module 310 drives the fine delay units 328A, such as capacitors, coupled to node F. Compared with the input signal 332, the intermediate signal 336 at node F is a distorted delay signal because of the characteristics of the fine delay units 328A.

Inverter module 324 receives the intermediate signal 336 and generates an output signal 334 at node R having an opposite phase to that of the intermediate signal 336. The inverter module 324 drives the fine delay units 328B, such as capacitors, coupled to node R. Compared with the intermediate signal 336, the output signal 334 at node R is a further distorted version of the intermediate signal 336 because of the characteristics of the fine delay units 328B. In at least one embodiment, the delay circuit blocks 322A and 322B have the same configuration and the fine delay units 328A and corresponding delay units 328B in each of the delay circuit blocks 322A and 322B are simultaneously selected to be coupled to the nodes F and R. Accordingly, the delay circuit blocks 322A and 322B cause distortions to the rising edge and falling edge of the input signal 332 in sufficiently the same manner. As a result, compared with the intermediate signal 336, the output signal 334 closely resembles the input signal 332 with regard to pulse shape and pulse width. In at least one embodiment, when the difference in pulse widths of the input signal 332 and the output signal 334 is less than 1%, the pulse shapes and the pulse widths of the input signal 332 and the output signal 334 are considered sufficiently matching with each other.

Therefore, in some embodiments, the first delay circuit block 322A causes a first distortion to be applied to the input signal 332. The second delay circuit block 322B causes a second distortion to be applied to the intermediate signal 336 in a manner similar to the first distortion. In at least one embodiment, the second distortion caused by the second delay circuit block 322B is used to counter the first distortion caused by the first delay circuit block 322A. As a result, if the input signal has an initial pulse shape or an initial pulse width and the output signal has a final pulse shape or a final pulse width, in at least one embodiment, the initial pulse shape or width matches the final pulse shape or width.

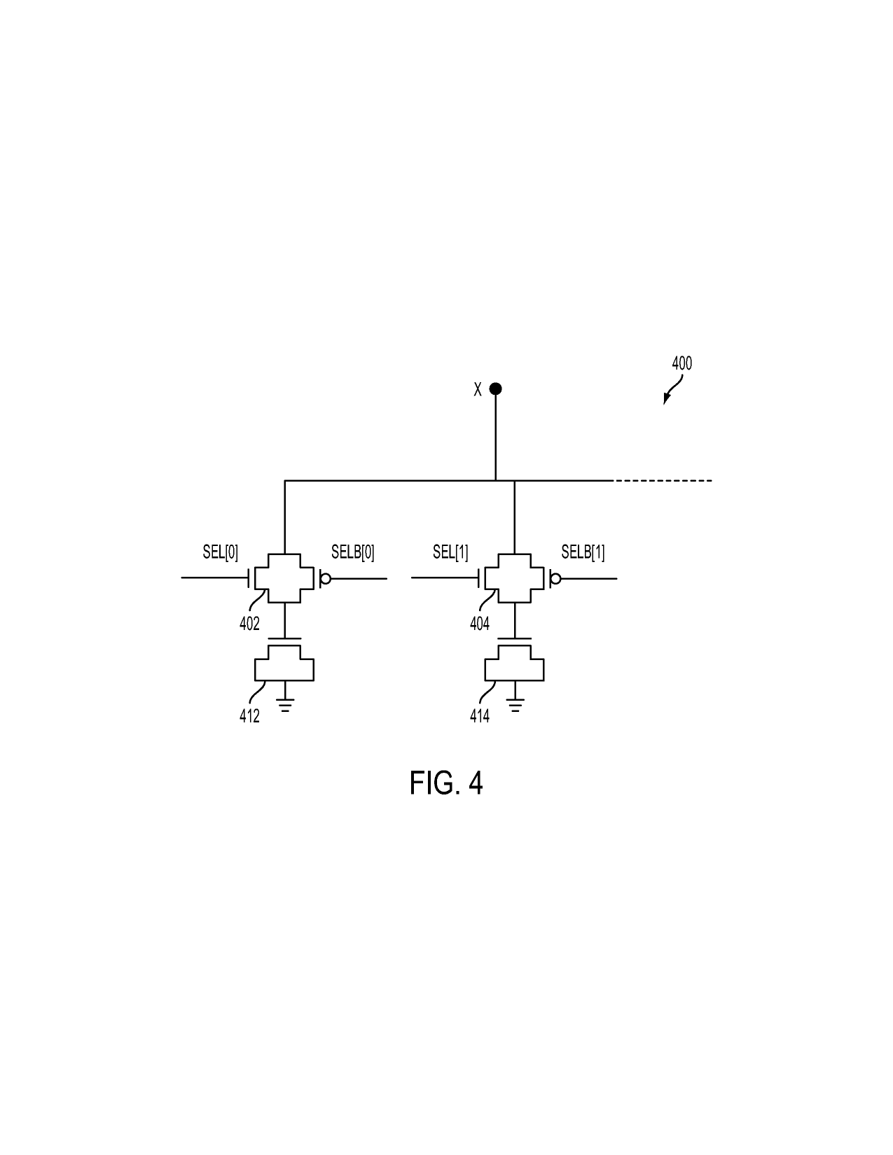

FIG. 4 is a block diagram of a delay circuit block 400 usable as delay circuit block 322A or 322B of FIG. 3 in accordance with one or more embodiments. Delay circuit block 400 includes transmission gates 402 and 404 and MOSFET capacitors 412 and 414 used as the delay unit 328A and 328B. Each transmission gate 402 and 404 has at least one p-type MOSFET and an n-type MOSFET used to selectively couple the corresponding MOSFET capacitor 412 and 414 to node X. In some embodiments, node X corresponds to node F or node R in FIG. 3, transmission gates 402 and 404 correspond to switches 327A and 327B in FIG. 3, and MOSFET capacitors 412 and 414 correspond to the delay units 328A and 328B in FIG. 3. The MOSFET capacitors 412 and 414 have different characteristics when forward biased or reversed biased. By having the inverter module 324 and the separately arranged delay circuit block 322A or 322B, similar levels of distortion are caused at the rising and falling edges of a delayed signal generated in response to an input signal. Accordingly, distortion effects applied to the delayed signal 334 by the delay circuit block 322A or 322B balance out each other.

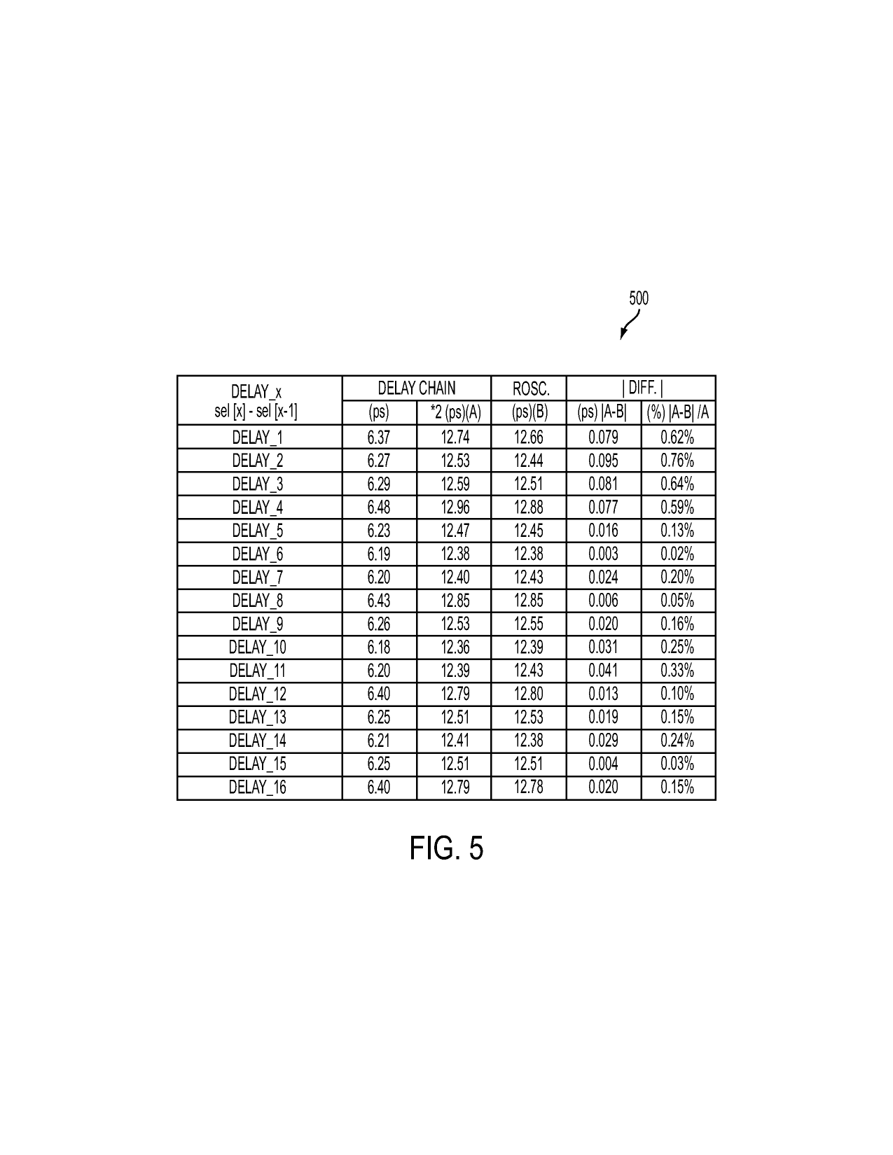

FIG. 5 is a table of the simulation results associated with the application of a delay circuit 300 of FIG. 3. Table 500 shows the percentage change in the pulse width of a time delayed signal processed using the delay circuit 300 of FIG. 3. The “Delay Chain” column lists the time delay caused by different ones of the fine delay units 328A and their corresponding ones of the delay units 328B. The “ROSC” column lists the pulse period of a delay oscillating circuit output generated based on the delay circuit 300. The “Diff” column tabulates the percent difference in pulse width of the output signal compared to the time delay of the selected pair of fine delay units 328A and 328B and shows the percent difference to be less than 1 percent. The comparison results represent that the pulse width of the time delayed output signal substantially matches that of the received input signal. Substantially matching the pulse width allows the input signal to be time delayed without impacting the integrated circuit timing relationships or degrading the performance of the integrated circuit.

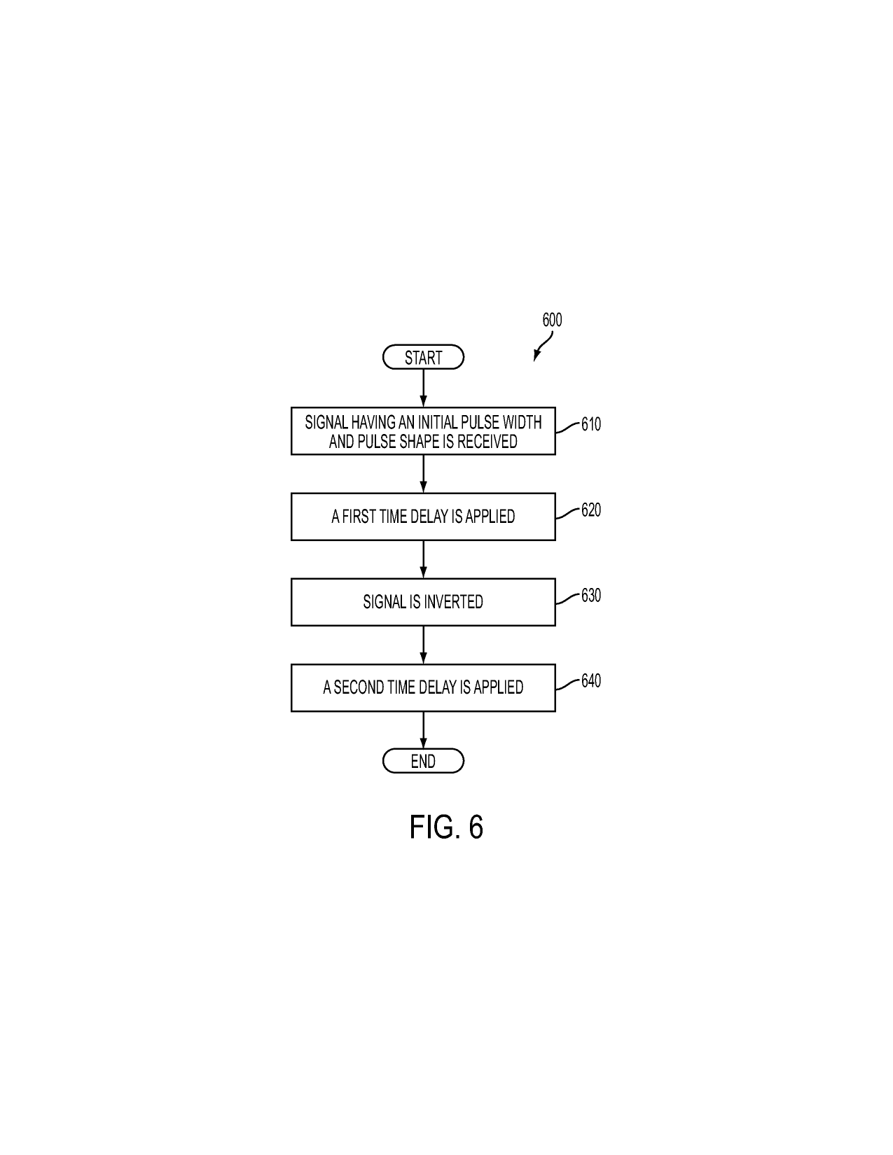

FIG. 6 is a flowchart of a method 600 of generating a delayed signal in accordance with one or more embodiments. It is understood that additional operations may be performed before, during, and/or after the method 600 depicted in FIG. 6, and that some other operations may only be briefly described herein. The embodiment depicted in FIG. 3 is also referred to in furtherance of the description of the method 600.

Operations 600 begin with block 610 in which an input signal 322 having an initial pulse width and pulse shape is received. In block 620, an intermediate signal 336 is generated by applying a first timing delay to the input signal. In some embodiments, the first time delay is caused by a first time delay circuit block 322A. In at least some embodiments, the first time delay is caused by charging or discharging one or more capacitors that have different characteristics when forward biased or reversed biased. Time delay circuit block 322A alters the pulse width and pulse shape of the received input signal 332. In block 630, following the application of the first time delay, the intermediate signal 336 is inverted. In block 640, an output delayed signal 334 is generated by applying a second time delay to the inverted intermediate signal. In some embodiments, the second time delay is caused by a second time delay circuit block 322B. In at least one embodiment, the second time delay is caused by charging or discharging one or more capacitors that have different characteristics when forward biased or reversed biased. The distortions caused by the time delay circuit block 322A and 322B are substantially the same, and thus the resulting signal 334 after performing the method 600 is a delayed version of the input signal 322, and the output delayed signal 334 more closely resembles the input signal 322 than the intermediate signal 336.

In at least some embodiments, a delay circuit includes an input port, an output port, a first delay circuit block, a second delay circuit block, and an inverter module. The input port is configured to receive an input signal. The output port is configured to output a delayed signal relative to the input signal. The first delay circuit block is coupled to the input port and configured to generate an intermediate signal by applying a first delay to the input signal. The inverter module has an input terminal and an output terminal. The input terminal of the inverter module is coupled to the first delay circuit block, and the inverter module is configured to generate an inverted intermediate signal at the output terminal. The second delay circuit block is coupled to the output terminal of the inverter module and configured to generate the delayed signal by applying a second delay to the inverted intermediate signal.

In at least one embodiment, a method of generating a delayed signal according to an input signal includes receiving the input signal. An intermediate signal is generated by applying a first time delay to the input signal by a first delay circuit block. The intermediate signal is inverted to generate an inverted intermediate signal. The delayed signal is generated by applying a second time delay to the inverted intermediate signal to generate the delayed signal.

In accordance with yet another embodiment, a delay circuit includes an input port, an output port, a first delay module, a second delay module, an inverter module, and a controller. The first delay module is coupled to the input port, and the first delay module has a first set of time delay units. The inverter module has an input and an output, the input of the inverter module is coupled to the first delay module, and the output of the inverter module is coupled to the output port. The second delay module is coupled to the output of the inverter module and the output port, and the second delay module has a second set of time delay units. The first and second sets of time delay units have the same configuration. The controller is coupled to the first and second delay module and configured to enable at least one of the first set of time delay units and at least a counterpart one of the second set of time delay units.

While the description is presented by way of examples and in terms of specific embodiments, it is to be understood that the invention is not limited to the disclosed embodiments. To the contrary, it is intended to cover various modifications and similar arrangements (as would be apparent to those skilled in the art). The above description discloses example steps. Steps can be added, replaced, change in order, and/or eliminated as appropriate, in accordance with the spirit and scope of the description. Embodiments that combine different claims and/or different embodiments are within the scope of the description and will be apparent to those skilled in the art after reviewing this disclosure. Therefore, the scope of the appended claims should be accorded the broadest interpretation so as to encompass all such modifications and similar arrangements.

1. A delay circuit comprising:
an input port configured to receive an input signal;
an output port configured to output a delayed signal relative to the input signal;
a first delay circuit block coupled to the input port and configured to generate an intermediate signal by applying a first delay to the input signal;
an inverter module having an input terminal and an output terminal, the input terminal of the inverter module coupled to the first delay circuit block, and the inverter module being configured to generate an inverted intermediate signal at the output terminal;
a second delay circuit block coupled to the output terminal of the inverter module and configured to generate the delayed signal by applying a second delay to the inverted intermediate signal; and
a coarse tuning module coupled between the input port and the first delay circuit block, the coarse tuning module being configured to apply an adjustable coarse delay to the input signal.

2. The delay circuit of claim 1, wherein:
the first delay circuit block is configured to cause a first distortion to the input signal; and
the second delay circuit block is configured to cause a second distortion of the intermediate signal in a manner similar to the first distortion.

3. The delay circuit of claim 1, wherein:
the first delay circuit block comprises a first switch coupled with a first capacitor; and
the second delay circuit block comprises a second switch coupled with a second capacitor, the first and second capacitors having the same capacitance.

4. The delay circuit of claim 1, wherein
the first delay circuit block comprises a set of switches each coupled with a corresponding capacitor;
the second delay circuit block comprises a set of switches each coupled with a corresponding capacitor; and
a switch of the set of switches in the first delay circuit block and a counterpart switch of the set of switches in the second delay circuit block are turned on in response to the same control signal.

5. (canceled)

6. The delay circuit of claim 1, wherein the input signal has an initial pulse shape, the delayed signal has a final pulse shape, and the initial pulse shape sufficiently matches the final pulse shape.

7. The delay circuit of claim 1, wherein the inverter module comprises an odd number of series-coupled inverters.

8. A method of generating a delayed signal according to an input signal, the method comprising:
receiving the input signal;
applying a coarse time delay to the input signal, the coarse time delay being adjustable;
generating an intermediate signal by applying a first time delay to the input signal by a first delay circuit block;
inverting the intermediate signal to generate an inverted intermediate signal; and
generating the delayed signal by applying a second time delay to the inverted intermediate signal by a second delay circuit block to generate the delayed signal.

9. The method of claim 8, wherein the inverting is performed by an odd number of inverters.

10. The method of claim 8, wherein the input signal has an initial pulse width, the delayed signal has a final pulse width, and the initial pulse width sufficiently matches the final pulse width.

11. The method of claim 8, further comprising:
causing a first distortion of the input signal by the first delay circuit block; and
causing a second distortion of the inverted intermediate signal by the second delay circuit block, and the second distortion being caused in a manner similar to the first distortion.

12. The method of claim 8, wherein the first time delay is caused by charging or discharging one or more of a first set of capacitors in the first delay circuit block.

13. The method of claim 8, wherein the second time delay is caused by charging or discharging one or more of a second set of capacitors in the second delay circuit block.

14. The method of claim 8, wherein
the first time delay is caused by charging or discharging one or more of a first set of capacitors in the first delay circuit block;
the second time delay is caused by charging or discharging one or more of a second set of capacitors in the second delay circuit block;
and the first set of capacitors and the second set of capacitors have the same characteristics.

15. (canceled)

16. The method of claim 8, wherein the input signal has an initial pulse shape, the delayed signal has a final pulse shape, and the initial pulse shape sufficiently matches the final pulse shape.

17. A delay circuit comprising:
an input port;
an output port;
a coarse tuning module having an input and an output, the input of the coarse tuning module coupled to the input port, the coarse tuning module being configured to apply an adjustable coarse delay to a signal at the input port;
a first delay module coupled to the output of the coarse tuning module, the first delay module comprising a first set of time delay units;
an inverter module having an input and an output, the input of the inverter module coupled to the first delay module, and the output of the inverter module coupled to the output port;
a second delay module coupled to the output of the inverter module and the output port, the second delay module comprising a second set of time delay units, the first and second set of time delay units have the same configuration; and
a controller coupled to the first and second delay module and configured to enable at least one of the first set of time delay units and at least a counterpart one of the second set of time delay units.

18. The delay circuit of claim 17, wherein the inverter module has one or more inverters.

19. The delay circuit of claim 17, wherein
the first delay module is configured to apply a first distortion to the signal at the input port;
the second delay module is configured to apply a second distortion to a signal at the output port; and
the second distortion is caused in a similar manner as the first distortion.

20. The delay circuit of claim 17, wherein each one of the first and second time delay units comprises a MOSFET configured as a capacitor
